(19) United States
(12) Patent Application Publication
(10) Pub. No.: US 2026/0371595 A1
(43) Pub. Date: Nov. 19, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Ji Hoon PARK, Gyeonggi-do (KR)

(21) Appl. No.: 19/375,219

(22) Filed: Oct. 31, 2025

(30) Foreign Application Priority Data
May 16, 2025 (KR) 10-2025-0063772

(51) Int. Cl. H10B 43/35; H10B 41/10; H10B 41/27; H10B 41/35; H10B 41/41; H10B 43/10; H10B 43/27; H10B 43/40; H10B 80/00; H10W 90/00

(52) U.S. Cl. CPC H10B 43/35; H10B 41/10; H10B 41/27; H10B 41/35; H10B 41/41; H10B 43/10; H10B 43/27; H10B 43/40; H10B 80/00; H10W 90/00; H10W 90/792

(57) ABSTRACT

A semiconductor device includes a substrate including a cell region and a peripheral circuit region spaced apart from the cell region in a first direction; a first source select line located in the cell region and extending in the first direction; a second source select line spaced apart from the first source select line in a second direction intersecting the first direction; a first source pattern located on the first source select line; a second source pattern located on the second source select line; a first group of channel structures extending into the first source pattern through the first source select line; and a second group of channel structures extending into the second source pattern through the second source select line.

### CROSS-REFERENCE TO RELATED APPLICATION

This application claims priority under 35 U.S.C. § 119 to Korean Patent Application No. 10-2025-0063772 filed on May 16, 2025, which is incorporated herein by reference in its entirety.

### BACKGROUND

### 1. Technical Field

Embodiments of the present disclosure relate generally to an electronic device and a method of manufacturing the electronic device and, more particularly, to a semiconductor device and a method of manufacturing the semiconductor device.

### 2. Related Art

The degree of integration of a semiconductor device is mainly determined by an area occupied by a unit memory cell. Recently, as improvements in the degree of integration of a semiconductor device for forming memory cells in a single layer on a substrate have reached a limit, a three-dimensional semiconductor device for stacking memory cells on a substrate has been proposed. Furthermore, for improving the operational reliability of such a semiconductor device, various structures and manufacturing methods have been developed. However, further improvements are needed.

### SUMMARY

In an embodiment of the present disclosure, a semiconductor device may include a substrate including a cell region and a peripheral circuit region spaced apart from the cell region in a first direction; a first source select line located in the cell region and extending in the first direction; a second source select line spaced apart from the first source select line in a second direction intersecting the first direction; a first source pattern located on the first source select line; a second source pattern located on the second source select line; a first group of channel structures extending into the first source pattern through the first source select line; and a second group of channel structures extending into the second source pattern through the second source select line.

In an embodiment of the present disclosure, a method of manufacturing a semiconductor device may include forming a first sacrificial layer; forming a sacrificial separation structure in the first sacrificial layer; forming a second sacrificial layer on the first sacrificial layer; forming a stack by alternately stacking first material layers and second material layers on the second sacrificial layer; forming a first group of channel structures and a second group of channel structures that extend into the second sacrificial layer through the stack; forming a slit extending through the stack; forming a gate structure by replacing the second material layers with third material layers through the slit; forming an opening by removing the sacrificial separation structure; separating the second sacrificial layer into sacrificial patterns by extending the opening; and forming a source separation structure in the opening.

In an embodiment of the present disclosure, a method of manufacturing a semiconductor device may include forming a stack by alternately stacking first material layers and second material layers on a substrate; forming a first group of channel structures and a second group of channel structures that extend into the substrate through the stack; forming a slit extending through the stack; forming a gate structure by replacing the second material layers with third material layers through the slit; exposing the first group of channel structures and the second group of channel structures by removing the substrate; forming a source layer connected to the first group of channel structures and the second group of channel structures; forming an opening extending between the first group of channel structures and the second group of channel structures through the source layer; and forming a source separation structure in the opening.

In an embodiment of the present disclosure, a semiconductor device comprising a substrate including a cell region; a first source select line located in the cell region and extending in a first direction; a second source select line located in the cell region and extending in the first direction; a first source pattern located on the first source select line; a second source pattern located on the second source select line; channel structures extending into the first and second source patterns through the first and second source select lines respectively, wherein the first source select line and the first source pattern are separated from the second select line and the second source pattern by a source separation structure.

### BRIEF DESCRIPTION OF THE DRAWINGS

FIGS. 1A, 1B, 1C, and 1D are diagrams illustrating a semiconductor device in accordance with an embodiment of the present disclosure.

FIGS. 2A, 2B, 2C, and 2D, FIGS. 3A, 3B, 3C, and 3D, FIGS. 4A, 4B, and 4C, FIGS. 5A, 5B, 5C, and 5D, FIGS. 6A, 6B, 6C, and 6D, and FIGS. 7A and 7B are diagrams illustrating a method of manufacturing a semiconductor device in accordance with an embodiment of the present disclosure.

FIGS. 8A, 8B, and 8C are diagrams illustrating a method of manufacturing a semiconductor device in accordance with an embodiment of the present disclosure.

### DETAILED DESCRIPTION

Various embodiments of the present disclosure are directed to a semiconductor device having a stable structure and improved characteristics and a method of manufacturing the semiconductor device.

According to the present technology, it is possible to provide a semiconductor device having a stable structure and improved reliability.

Hereafter, embodiments in accordance with the technical spirit of the present disclosure will be described with reference to the accompanying drawings.

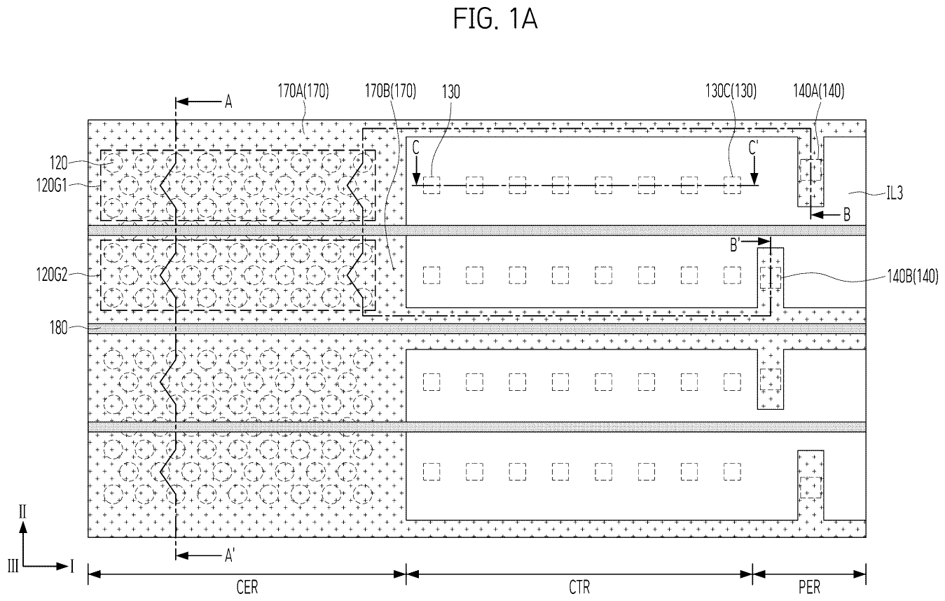

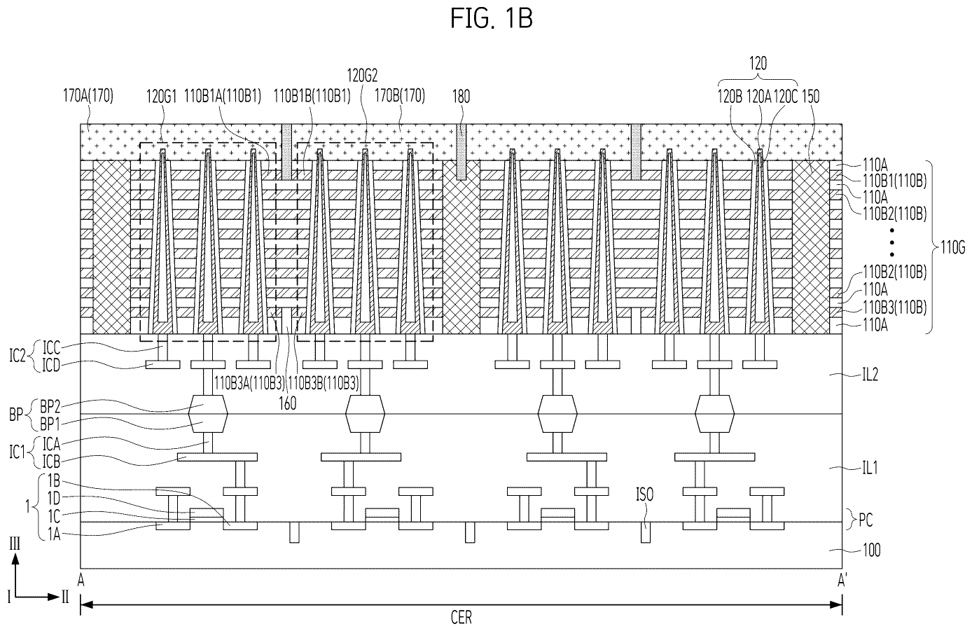

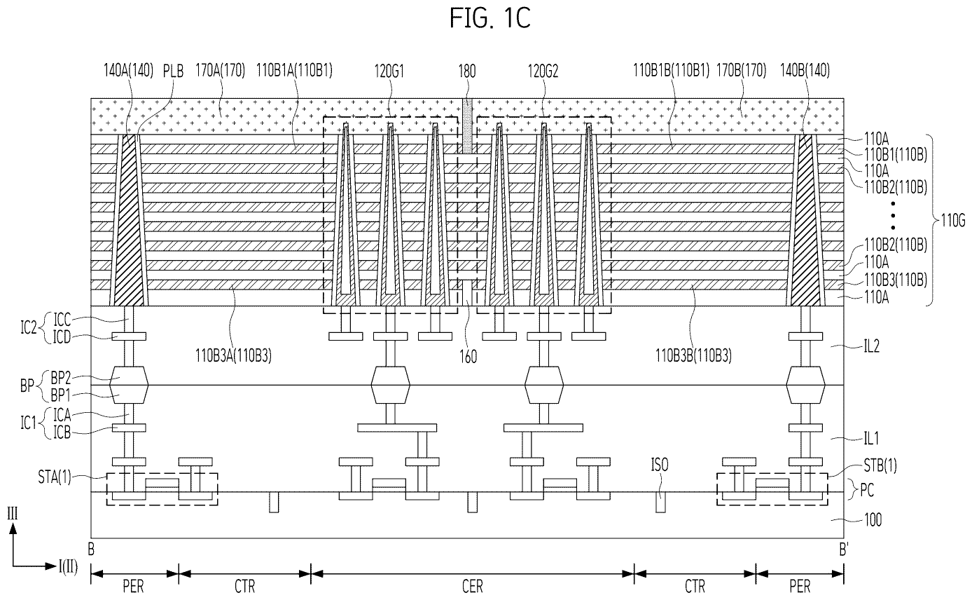

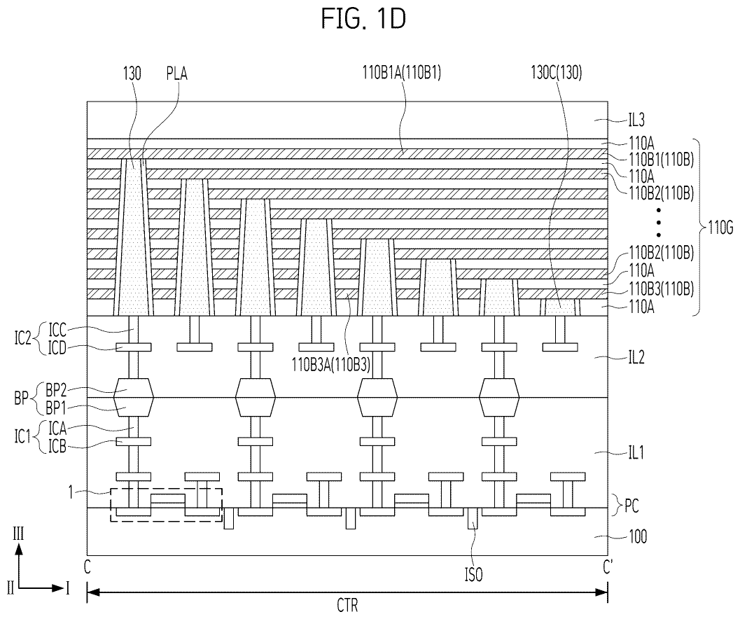

FIGS. 1A, 1B, 1C, and 1D are diagrams illustrating a semiconductor device in accordance with an embodiment of the present disclosure. FIG. 1A is a plan view, FIG. 1B is a cross-sectional view taken along line A-A′ of FIG. 1A, FIG. 1C is a cross-sectional view taken along line B-B′ of FIG. 1A, and FIG. 1D is a cross-sectional view taken along line C-C′ of FIG. 1A.

Referring to FIGS. 1A to 1D, the semiconductor device may include a substrate 100, a gate structure 110G formed over the substrate 100, and channel structures 120 spaced apart and passing through the gate structure 110G. The semiconductor device may also include contact vias 130, contact plugs 140, slit structures 150, drain separation structures 160, source patterns 170, and source separation structures 180. The semiconductor device may further include a peripheral circuit PC, an element isolation layer ISO, a first interlayer insulating layer IL1, a second interlayer insulating layer IL2, a third interlayer insulating layer IL3, a first interconnection structure IC1, a second interconnection structure IC2, a bonding structure BP, first barrier layers PLA, and second barrier layers PLB.

The substrate 100 may include a cell region CER and a peripheral circuit region PER spaced apart from the cell region CER in a first direction I. The substrate 100 may further include a contact region CTR located between the cell region CER and the peripheral circuit region PER. The cell region CER may be a region where memory cells are located. The peripheral circuit region PER may be a region where the peripheral circuit PC such as a transistor 1 is located. The contact region CTR may be a region where contact structures such as the contact vias 130 electrically connected to the memory cells of the cell region CER are located.

The peripheral circuit PC may be located on the substrate 100. The peripheral circuit PC may be located in the peripheral circuit region PER. However, the embodiments of the present disclosure are not limited thereto, and the peripheral circuit PC may be located in the cell region CER and/or the contact region CTR. The peripheral circuit PC may include the transistor 1, a capacitor, and the like. The transistor 1 may include junctions 1A and 1B, a gate electrode 1D, and a gate insulating layer 1C. For example, the gate insulating layer 1C may be located between the gate electrode 1D and the substrate 100. The element isolation layer ISO may be located in the substrate 100, an active region may be defined by the element isolation layer ISO, and the transistor 1 may be located in the active region.

The transistor 1 may include channel select transistors located in the cell region CER, gate line transistors located in the contact region CTR, and source select transistors located in the peripheral circuit region PER. The channel select transistors may be electrically connected to the channel structures 120, the gate line transistors may be electrically connected to the contact vias 130, and the source select transistors may be electrically connected to the contact plugs 140. For example, the source select transistors may include a first source select transistor STA and a second source select transistor STB.

The first interconnection structure IC1 may be located on the peripheral circuit PC, and may be located in the first interlayer insulating layer IL1. For example, the first interlayer insulating layer IL1 may be located on the substrate 100. The first interconnection structure IC1 may include first vias ICA and first wiring lines ICB. At least one of the first vias ICA may be connected to the peripheral circuit PC. At least one of the first vias ICA may be connected to the bonding structure BP. At least one of the first wiring lines ICB may connect the first vias ICA to each other. The first interconnection structure IC1 may include a conductive material such as tungsten.

The bonding structure BP may be located on the first interconnection structure IC1. The bonding structure BP may include first bonding pads BP1 and second bonding pads BP2. The first bonding pads BP1 may be located in the first interlayer insulating layer IL1, and the second bonding pads BP2 may be located in the second interlayer insulating layer IL2. For example, the second interlayer insulating layer IL2 may be located on the first interlayer insulating layer IL1. The bonding structure BP may be electrically connected to the peripheral circuit PC through the first interconnection structure IC1. The bonding structure BP may include a conductive material such as copper.

The second interconnection structure IC2 may be located on the bonding structure BP, and may be located in the second interlayer insulating layer IL2. The second interconnection structure IC2 may include second vias ICC and second wiring lines ICD. At least one of the second vias ICC may be connected to one of the channel structures 120, the contact vias 130, or the contact plugs 140. At least one of the second vias ICC may be connected to the bonding structure BP. At least one of the second wiring lines ICD may connect the second vias ICC to each other. At least one of the second wiring lines ICD may be a bit line electrically connected to the channel structures 120. The second interconnection structure IC2 may include a conductive material such as tungsten.

The gate structure 110G may be located in the cell region CER. However, the embodiments of the present disclosure are not limited thereto, and the gate structure 110G may extend in the first direction I from the cell region CER to the contact region CTR. Alternatively, the gate structure 110G may extend in the first direction I from the cell region CER to the peripheral circuit region PER through the contact region CTR. The gate structure 110G may be located on the second interconnection structure IC2. The gate structure 110G may include insulating layers 110A and conductive layers 110B that are alternately stacked. The conductive layers 110B may be gate lines. The insulating layers 110A may each include an insulating material such as oxide, and the conductive layers 110B may each include a conductive material such as tungsten, molybdenum, or polysilicon.

The gate lines may be source select lines 110B1, word lines 110B2, and drain select lines 110B3. A conductive layer located at the uppermost portion among the conductive layers 110B may be the source select line 110B1, a conductive layer at the lowermost portion among the conductive layers 110B may be the drain select line 110B3, and conductive layers located between the source select line 110B1 and the drain select line 110B3 may be the word lines 110B2.

The source select lines 110B1 may include a first source select line 110B1A and a second source select line 110B1B spaced apart from the first source select line 110B1A in a second direction II. The drain select lines 110B3 may include a first drain select line 110B3A and a second drain select line 110B3B spaced apart from the first drain select line 110B3A in the second direction II. For example, the first source select line 110B1A and the first drain select line 110B3A may be located in regions corresponding to each other, and the second source select line 110B1B and the second drain select line 110B3B may be located in regions corresponding to each other.

The source patterns 170 may be located on the gate structure 110G. The source patterns 170 may extend in the first direction I from the cell region CER to the peripheral circuit region PER. The source patterns 170 may include a first source pattern 170A and a second source pattern 170B spaced apart from the first source pattern 170A in the second direction II. The first source pattern 170A may be located on the first source select line 110B1A, and the second source pattern 170B may be located on the second source select line 110B1B.

The source separation structures 180 may be located in the cell region CER, and may extend in the first direction I to the contact region CTR and/or the peripheral circuit region PER. At least one of the source separation structures 180 may be located between the first source pattern 170A and the second source pattern 170B, and may extend between the first source select line 110B1A and the second source select line 110B1B. In addition, one of the source separation structures 180 may be located between the first source pattern 170A and the second source pattern 170B and may extend into one of the slit structures 150. The source separation structures 180 may separate a source layer configured as a single layer into the first and second source patterns 170A and 170B. In addition, the source separation structures 180 may separate a source select line configured as a single layer into the first and second source select lines 110B1A and 110B1B. The source separation structures 180 may each include an insulating material such as oxide.

The drain separation structures 160 may be located in the cell region CER, and may extend in the first direction I to the contact region CTR and/or the peripheral circuit region PER. At least one of the drain separation structures 160 may be located between the first drain select line 110B3A and the second drain select line 110B3B. For example, the drain separation structures 160 may be located in regions corresponding to the source separation structures 180. The drain separation structures 160 may separate a drain select line configured as a single layer into the first and second drain select lines 110B3A and 110B3B. The drain separation structures 160 may each include an insulating material such as oxide.

For reference, the drain select lines 110B3 might not be located in regions corresponding to the source select lines 110B1. For example, the drain separation structures 160 might not be located in regions corresponding to the source separation structures 180, and in such a case, the drain select lines 110B3 might not be located in regions corresponding to the source select lines 110B1. The number of drain select lines 110B3 may be different from the number of source select lines 110B1. In addition, the number of drain separation structures 160 may be different from the number of source separation structures 180.

The channel structures 120 may be located in the cell region CER. The channel structures 120 may extend into the source patterns 170, respectively, through the gate structure 110G. For example, a first group of channel structures 120G1 may extend into the first source pattern 170A through the first source select line 110B1A. A second group of channel structures 120G2 may extend into the second source pattern 170B through the second source select line 110B1B. At least one of the channel structures 120 may be connected to the peripheral circuit PC through the second interconnection structure IC2, the bonding structure BP, and the first interconnection structure IC1. The channel structures 120 may be electrically connected to the channel select transistors of the peripheral circuit PC.

Each of the channel structures 120 may include a channel layer 120A, a memory layer 120B surrounding the channel layer 120A, and an insulating core 120C located in the channel layer 120A. For example, the channel layers 120A of the channel structures 120 may be connected to the source patterns 170. Memory cells may be located in regions where the channel structures 120 and the conductive layers 110B intersect each other, and may be stacked to constitute a memory string.

The contact vias 130 may be located in the contact region CTR. The contact vias 130 may extend through the gate structure 110G, and may be connected to the conductive layers 110B, respectively. For example, the contact vias 130 may be connected to the first and second source select lines 110B1A and 110B1B, the word lines 110B2, and the first and second drain select lines 110B3A and 110B3B, respectively. The third interlayer insulating layer IL3 may be located on the contact vias 130. For example, the third interlayer insulating layer IL3 may be located at a level corresponding to the source patterns 170.

At least one of the contact vias 130 may be connected to the peripheral circuit PC through the second interconnection structure IC2, the bonding structure BP, and the first interconnection structure IC1. The contact vias 130 may be electrically connected to the gate line transistors of the peripheral circuit PC. Sidewalls of the contact vias 130 may be covered by the first barrier layers PLA. For example, the first barrier layers PLA may insulate the remaining conductive layers 110B excluding the conductive layer 110B connected to the contact via 130 and the contact via 130 from each other. The contact vias 130 may each include a conductive material such as tungsten, and the first barrier layers PLA may each include an insulating material such as oxide.

The contact plugs 140 may be located in the peripheral circuit region PER. The contact plugs 140 may extend through the gate structure 110G, and may be connected to the source patterns 170, respectively. For example, a first contact plug 140A may extend through the gate structure 110G, and may be connected to the first source pattern 170A. A second contact plug 140B may extend through the gate structure 110G, and may be connected to the second source pattern 170B. At least one of the contact plugs 140 may be connected to the peripheral circuit PC through the second interconnection structure IC2, the bonding structure BP, and the first interconnection structure IC1. For example, the first contact plug 140A may electrically connect the first source select transistor STA and the first source pattern 170A to each other. The second contact plug 140B may connect the second source select transistor STB and the second source pattern 170B to each other.

The sidewalls of the contact plugs 140 may be covered by the second barrier layers PLB for insulating the conductive layers 110B and the contact plugs 140 from each other. The contact plugs 140 may each include a conductive material such as tungsten, and the second barrier layers PLB may each include an insulating material such as oxide.

The slit structures 150 (see FIG. 1B) may extend through the gate structure 110G. The slit structures 150 may extend in the first direction I from the cell region CER to the peripheral circuit region PER through the contact region CTR. The slit structures 150 may each include at least one of an insulating material, a semiconductor material, or a conductive material.

Various control transistors may be used to selectively control memory strings including stacked memory cells, gate lines of a gate structure, and a source structure connected to the memory strings. For example, channel select transistors may be used to selectively connect or disconnect the memory strings to or from each other. In addition, gate line transistors may be used to select word lines and turn on/off memory cells corresponding to the selected word lines, to connect or disconnect the memory strings to or from the source structure through source select lines, and to connect or disconnect the memory strings to or from a bit line through drain select lines. In addition, source select transistors may be used to selectively ground the source structure connected to the memory strings or apply a voltage to the source structure.

However, when a voltage is applied to the transistors to control such structures, unintended electrical interference may occur in adjacent structures that are not control targets. For example, when a first group of memory strings are selected and a ground voltage is applied to the first group of memory strings through the source structure, the source structure is formed as a single layer shared with another group of memory strings, and thus, a second group of memory strings that are not control targets may also be affected by source bouncing. In such a case, an unintended current flow may occur in the second group of memory strings, and accordingly, a malfunction may be caused.

According to an embodiment of the present disclosure, the first group of channel structures 120G1 may be connected to the first source pattern 170A, and the second group of channel structures 120G2 may be connected to the second source pattern 170B. In addition, the first source pattern 170A may be electrically connected to the first source select transistor STA through the first contact plug 140A. Also, the second source pattern 170B may be electrically connected to the second source select transistor STB through the second contact plug 140B. In such a case, even though a voltage is applied to the first source pattern 170A through the first source select transistor STA, the second group of channel structures 120G2 is not affected. In addition, even though a voltage is applied to the second source pattern 170B through the second source select transistor STB, the first group of channel structures 120G1 is not affected. During a selection operation and an erase operation of the memory cells, the occurrence of electrical interference between different groups of channel structures may be prevented or reduced, and a voltage may be selectively applied only to a desired memory string. Accordingly, it is possible to improve the reliability of the semiconductor device.

For reference, the expressions for directions such as an ‘upper portion’ or a ‘lower portion’ as used herein are based on a reference direction set for convenience of description in consideration of the fact that a cell wafer including memory cells is flipped and bonded to a peripheral circuit wafer in a process of manufacturing a semiconductor device. For example, it is described in the present disclosure that some components such as a ‘source select line’ are ‘located at the uppermost portion’, but they may also be located at the ‘lowermost portion’. Accordingly, the expressions for directions as used herein are not limited to specific directions.

According to the structure described above, the source separation structures 180 may be located between the first source pattern 170A and the second source pattern 170B, and may extend between the first source select line 110B1A and the second source select line 110B1B. In addition, the source patterns 170A and 170B may be connected to the corresponding source select transistors STA and STB through the contact plugs 140A and 140B, respectively. In such a case, it is possible to prevent electrical interference between different groups of channel structures from occurring during the selection operation and the erase operation of the memory cells.

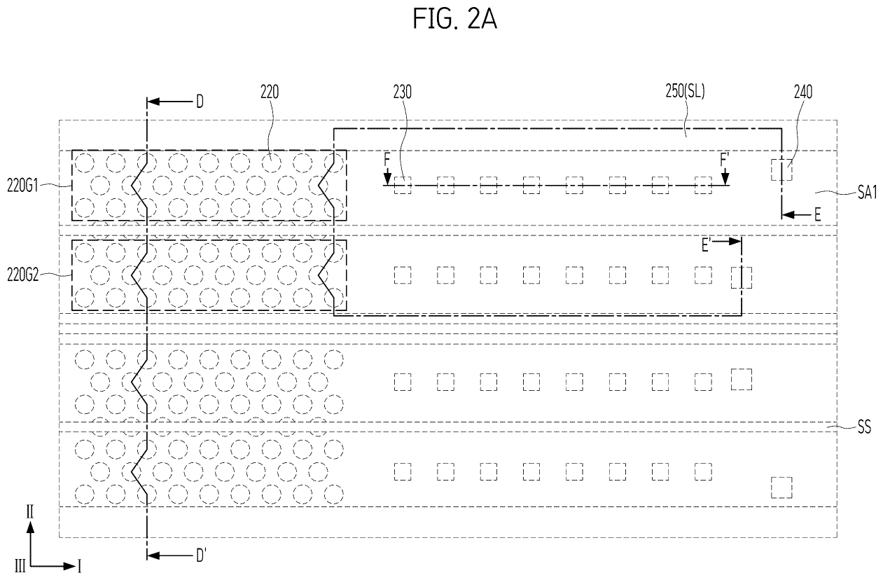

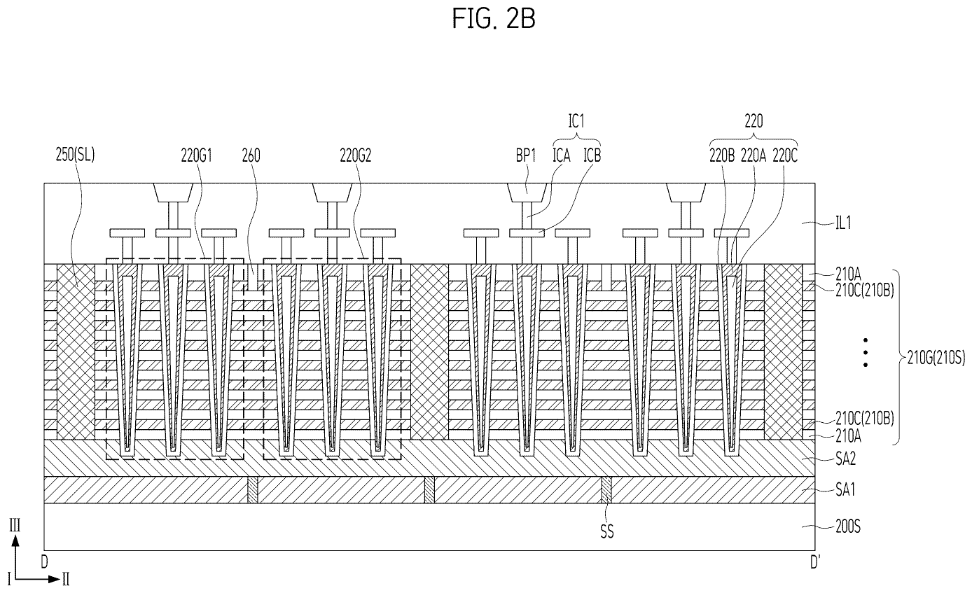

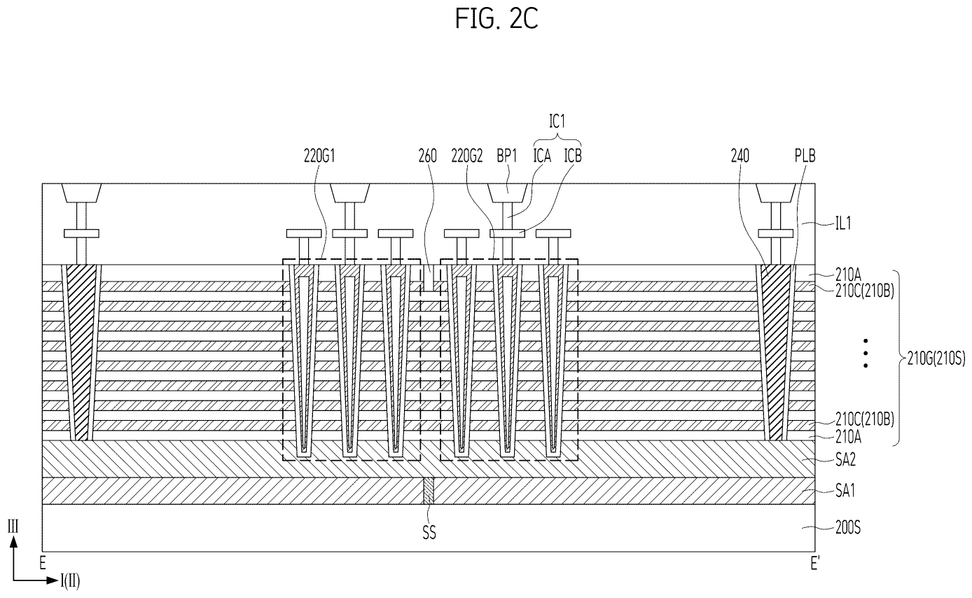

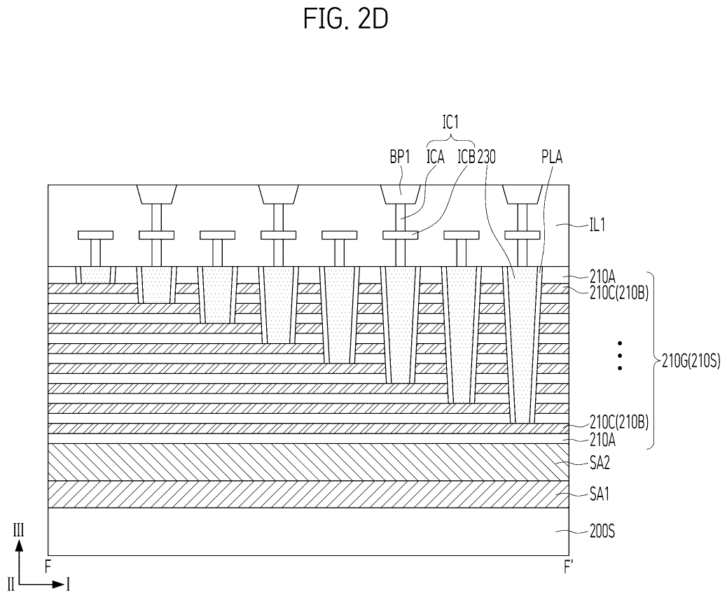

FIGS. 2A, 2B, 2C, and 2D, FIGS. 3A, 3B, 3C, and 3D, FIGS. 4A, 4B, and 4C, FIGS. 5A, 5B, 5C, and 5D, FIGS. 6A, 6B, 6C, and 6D, and FIGS. 7A and 7B are diagrams illustrating a method of manufacturing a semiconductor device in accordance with an embodiment of the present disclosure. FIGS. 2A, 3A, 4A, 5A, 6A, and 7A are plan views, FIGS. 2B, 3B, 4B, 5B, and 6B are cross-sectional views taken along lines D-D′ of FIGS. 2A, 3A, 4A, 5A, and 6A, respectively, FIGS. 2C, 3C, 4C, 5C, and 6C are cross-sectional views taken along lines E-E′ of FIGS. 2A, 3A, 4A, 5A, and 6A, respectively, FIGS. 2D, 3D, 5D, 6D, and 7B are cross-sectional views taken along lines F-F′ of FIGS. 2A, 3A, 5A, 6A, and 7A respectively. Hereinafter, content overlapping with previously described content will be omitted.

Referring to FIGS. 2A to 2D, a first sacrificial layer SA1 may be formed on a cell substrate 200S. For example, the first sacrificial layer SA1 may include an insulating material such as oxide or nitride. In an embodiment, the first sacrificial layer SA1 may include oxide. In another embodiment, the first sacrificial layer SA1 may include nitride.

Subsequently, a sacrificial separation structure SS may be formed in the first sacrificial layer SA1. For example, multiple sacrificial separation structures SS may be formed in the first sacrificial layer SA1 extending in the first direction I and spaced apart from each other in the second direction II intersecting the first direction I. The sacrificial separation structures SS may be formed in consideration of regions where source separation structures are to be formed in a subsequent process. For example, the sacrificial separation structures SS may be formed in regions corresponding to portions between different groups of channel structures so that the source separation structures may distinguish the different groups of channel structures from each other in a subsequent process.

The sacrificial separation structures SS may be made of a different material from the first sacrificial layer SA1 including, for example, a material having an etching selectivity with respect to the first sacrificial layer SA1. In an embodiment, the first sacrificial layer SA1 may include oxide, and the sacrificial separation structure SS may include nitride.

Subsequently, a second sacrificial layer SA2 may be formed on the first sacrificial layer SA1. The second sacrificial layer SA2 may include a different material from the first sacrificial layer SA1 and/or the sacrificial separation structure SS. In an embodiment, the second sacrificial layer SA2 may include polysilicon.

Subsequently, a stack 210S may be formed by alternately stacking first material layers 210A and second material layers 210B on the second sacrificial layer SA2. For example, the first material layers 210A may each include an insulating material such as oxide, and the second material layers 210B may each include a sacrificial material such as nitride.

Subsequently, channel structures 220 may be formed to pass through the stack 210S and extend partially into the second sacrificial layer SA2. The channel structures may include a first group of channel structures 220G1 and a second group of channel structures 220G2 which are spaced apart from each other in the second direction II. For example, one of the sacrificial separation structures SS may be located in a corresponding region between the first group of channel structures 220G1 and the second group of channel structures 220G2. The channel structures 220 formed in regions corresponding to the sacrificial separation structures SS may be dummy channel structures. Each of the channel structures 220 may include a channel layer 220A, a memory layer 220B surrounding the channel layer 220A, and an insulating core 22C located in the channel layer 220A.

Contact vias 230 (See FIG. 2D) may be formed to extend through the stack 210S. First, contact holes respectively exposing the second material layers 210B may be formed through the stack 210S. Subsequently, preliminary first barrier layers may be formed in the contact holes, respectively. Subsequently, the second material layers 210B may be exposed by etching bottom surfaces of the preliminary first barrier layers. In this case, the preliminary first barrier layers may be used as first barrier layers PLA surrounding sidewalls of the contact vias 230. Subsequently, the contact vias 230 may be formed by forming a conductive material such as tungsten in the contact holes.

Contact plugs 240 extending through the stack 210S may be formed, by first, forming plug holes exposing an upper surface of the second sacrificial layer SA2 through the stack 210S. However, the embodiments of the present disclosure are not limited thereto, and the plug holes may extend into the second sacrificial layer SA2. Subsequently, preliminary second barrier layers may be formed in the plug holes, respectively. Subsequently, the second sacrificial layer SA2 may be exposed by etching bottom surfaces of the preliminary second barrier layers. In this case, the preliminary second barrier layers may be used as second barrier layers PLB surrounding sidewalls of the contact plugs 240. Subsequently, the contact plugs 240 may be formed by forming a conductive material such as tungsten in the plug holes.

A slit SL (ee FIG. 2B) extending through the stack 210S may be formed. For example, a plurality of slits SL extending in the first direction I and spaced apart from each other in the second direction II may be formed. For example, the first group of channel structures 220G1 and the second group of channel structures 220G2 may be located between adjacent slits SL in the second direction II. For reference, the slits SL may expose the upper surface of the second sacrificial layer SA2. However, the embodiments of the present disclosure are not limited thereto, and the slits SL may extend into the second sacrificial layer SA2.

Drain separation structures 260 (See FIG. 2C) extending through the stack 210S may be formed. For example, drain separation structures 260 separating at least one of the second material layers 210B may be formed. A second material layer 210B formed at the uppermost portion among the second material layers 210B may be separated by the drain separation structures 260. For example, the drain separation structures 260 may each include an insulating material such as oxide.

Subsequently, a gate structure 210G may be formed by replacing the second material layers 210B with third material layers 210C through the slit SL. For example, the gate structure 210G may be formed by forming the third material layers 210C in regions formed by removing the second material layers 210B through the slits SL. For example, the third material layers 210C may each include a conductive material such as tungsten, molybdenum, or polysilicon.

The third material layers 210C may be gate lines. For example, the third material layers 210C may be used as a source select line, a drain select line, and word lines. A third material layer formed at the lowermost portion among the third material layers 210C may be used as the source select line, a third material layer formed at the uppermost portion among the third material layers 210C may be used as the drain select line, and third material layers located between the source select line and the drain select line among the third material layers 210C may be used as the word lines.

Subsequently, slit structures 250 may be formed in the slits SL, respectively, for example, by adding in the slits at least one of an insulating material, a semiconductor material, or a conductive material.

Subsequently, a first interconnection structure IC1 and first bonding pads BP1 located on the first interconnection structure IC1 may be formed on the gate structure 210G. For example, the first interconnection structure IC1 and the first bonding pads BP1 may be formed in a first interlayer insulating layer IL1. The first interlayer insulating layer IL1 may be formed on the gate structure 210G.

The first interconnection structure IC1 may include first vias ICA and first wiring lines ICB. At least one of the first vias ICA may be connected to one of the channel structures 220, the contact vias 230, or the contact plugs 240. At least one of the first vias ICA may be connected to the first bonding pads BP1. At least one of the first wiring lines ICB may connect the first vias ICA to each other. At least one of the first wiring lines ICB may be a bit line electrically connected to the channel structures 220. The first interconnection structure IC1 and/or the first bonding pads BP1 may each include a conductive material such as tungsten or copper.

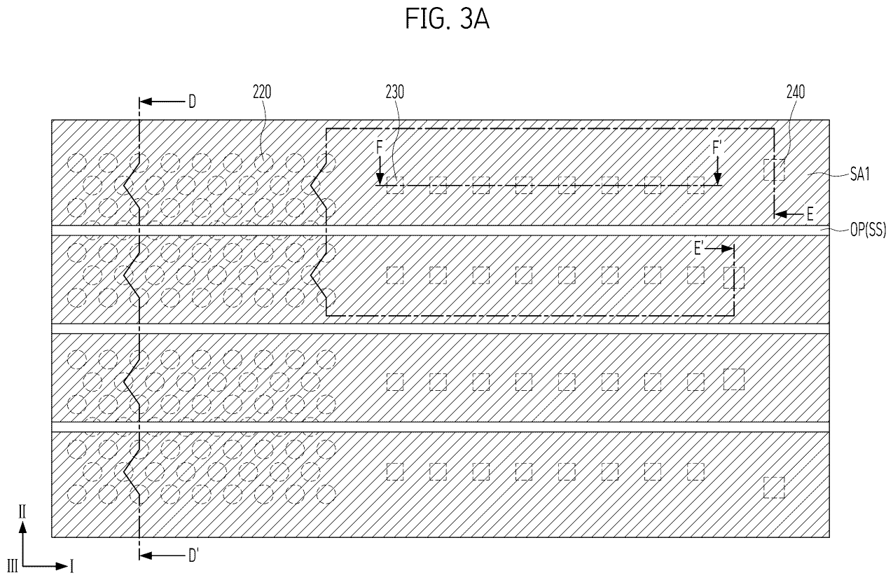

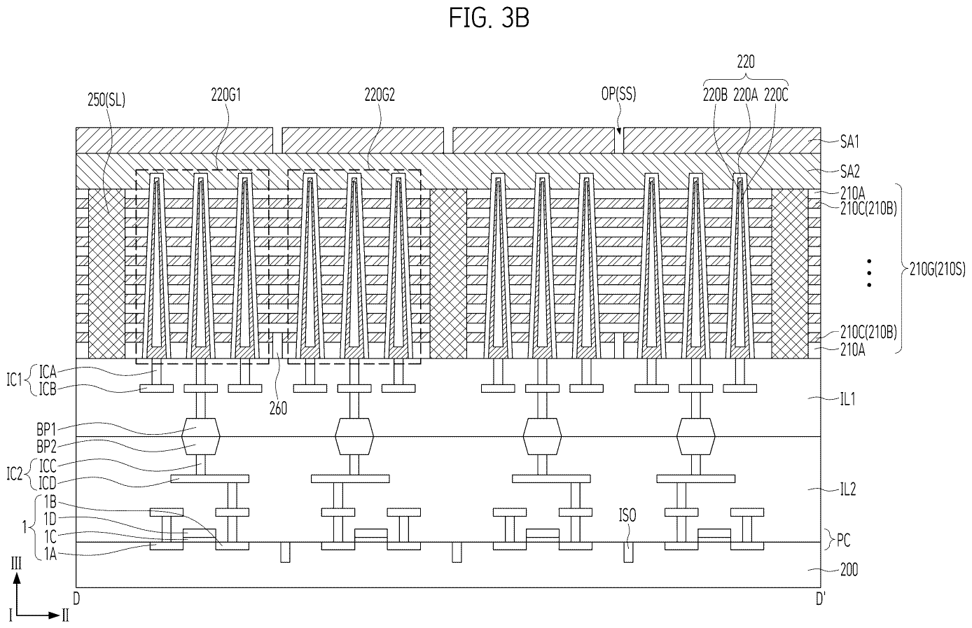

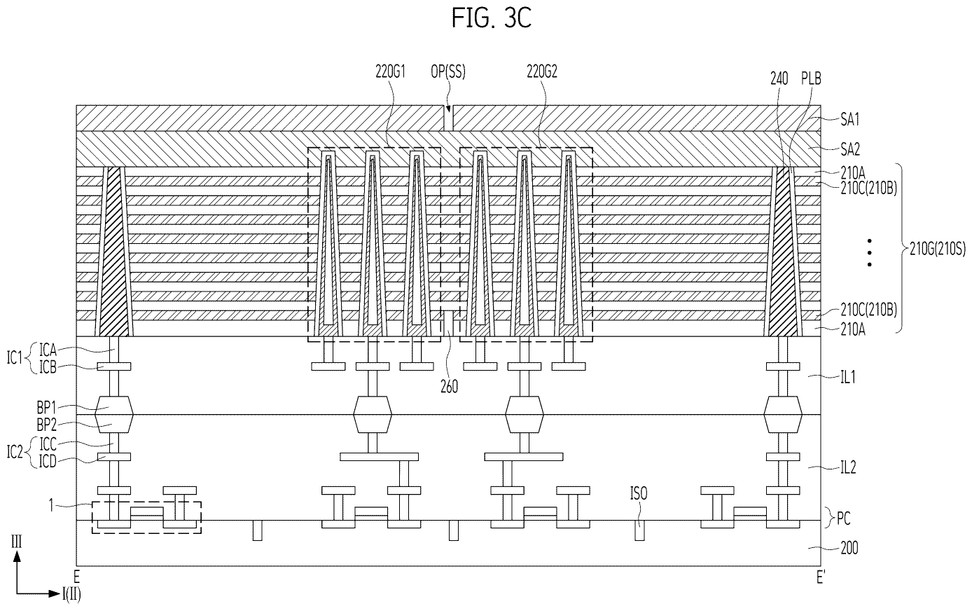

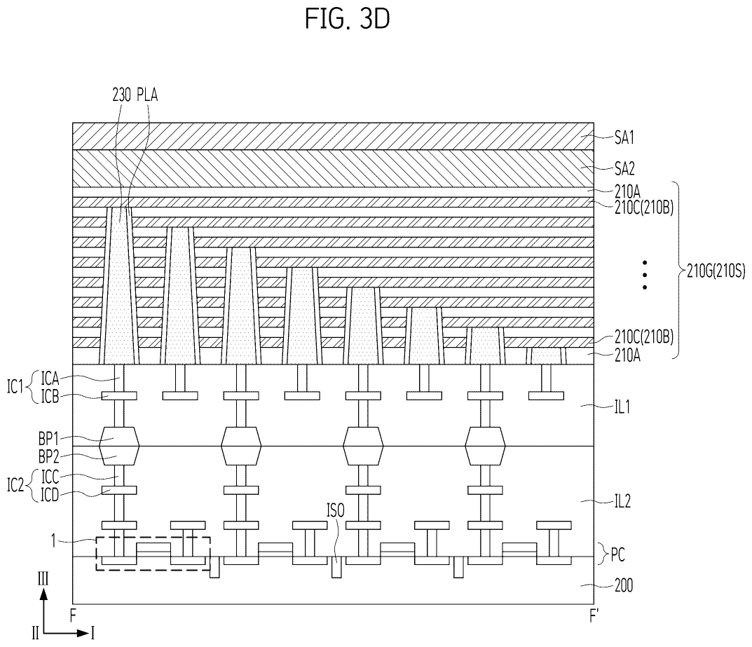

Referring now to FIGS. 3A to 3D, a peripheral circuit PC may be formed on a peripheral circuit board 200. The peripheral circuit PC may include a transistor 1, a capacitor, and the like. The transistor 1 may include junctions 1A and 1B, a gate electrode 1D, and a gate insulating layer 1C. For example, the gate insulating layer 1C may be located between the gate electrode 1D and the peripheral circuit board 200. An element isolation layer ISO may be located in the peripheral circuit board 200, an active region may be defined by the element isolation layer ISO, and the transistor 1 may be located in the active region.

For example, the transistors 1 may include channel select transistors for controlling memory strings, gate line transistors for controlling gate lines, and source select transistors for controlling a source structure. In a subsequent process, the channel select transistors may be electrically connected to the channel structures 220, the gate line transistors may be electrically connected to the contact vias 230, and the source select transistors may be electrically connected to the contact plugs 240.

Subsequently, a second interconnection structure IC2 and second bonding pads BP2 located on the second interconnection structure IC2 may be formed. For example, the second interconnection structure IC2 and the second bonding pads BP2 may be formed in a second interlayer insulating layer IL2. The second interlayer insulating layer IL2 may be formed on the peripheral circuit board 200.

The second interconnection structure IC2 may include second vias ICC and second wiring lines ICD. At least one of the second vias ICC may be connected to the peripheral circuit PC. At least one of the second vias ICC may be connected to second bonding pads BP2. At least one of the second wiring lines ICD may connect the second vias ICC to each other. The second interconnection structure IC2 and/or the second bonding pads BP2 may each include a conductive material such as tungsten or copper.

Consequently, a peripheral circuit wafer including the peripheral circuit board 200, the peripheral circuit PC, the second interlayer insulating layer IL2, the second interconnection structure IC2, and the second bonding pads BP2 may be formed. For reference, a cell wafer may include the cell substrate 200S, the first sacrificial layer SA1, the sacrificial separation structures SS, the second sacrificial layer SA2, the gate structure 210G, the channel structures 220, the contact vias 230, the contact plugs 240, the slit structures 250, the drain separation structures 260, the first interlayer insulating layer IL1, the first interconnection structure IC1, and the first bonding pads BP1.

Subsequently, the peripheral circuit wafer and the cell wafer may be bonded to each other. The first bonding pads BP1 and the second bonding pads BP2 may be bonded to each other to be in electrical communication. In some embodiments, the first bonding pads BP1 and the second bonding pads BP2 may be bonded to face each other. For example, the first bonding pads BP1 and the second bonding pads BP2 may be connected to each other, respectively. However, other configurations may also be used.

Subsequently, the cell substrate 200S may be removed and the first sacrificial layer SA1 and the sacrificial separation structures SS may be exposed.

Subsequently, openings OP may be formed by removing the sacrificial separation structures SS. For example, the sacrificial separation structures SS each may include a material having etching selectivity with respect to the first sacrificial layer SA1, and may thus be selectively removed. For example, the second sacrificial layer SA2 may be exposed by the openings OP.

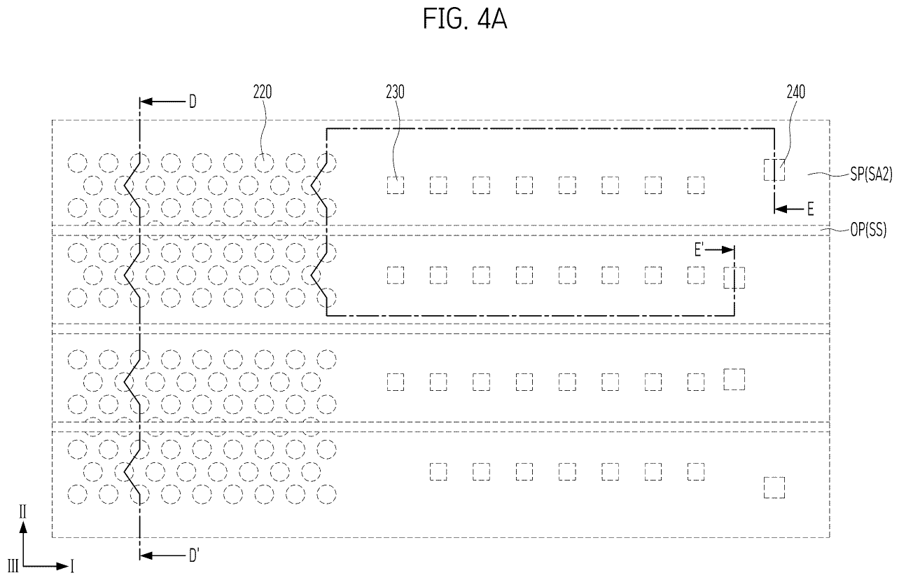

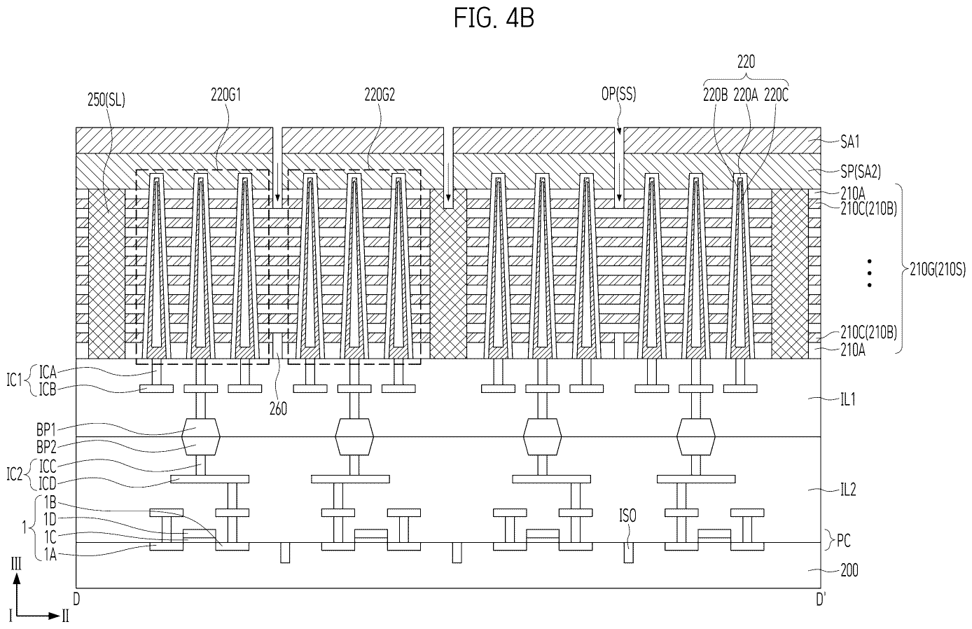

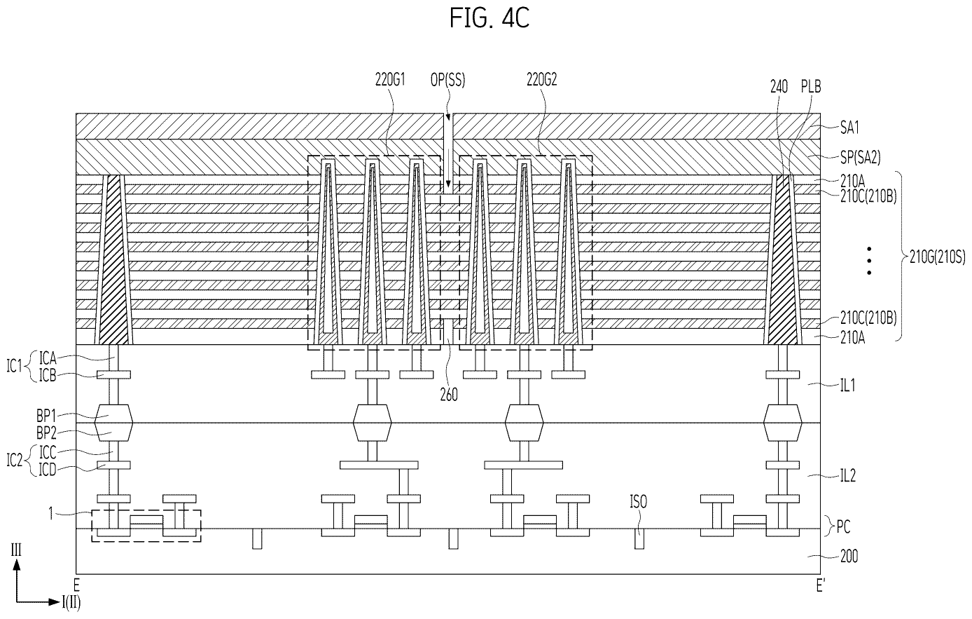

Referring to FIGS. 4A to 4C, the second sacrificial layer SA2 may be separated into sacrificial patterns SP by extending the openings OP. The openings OP may be extended into the gate structure 210G. For example, at least one of the third material layers 210C may be separated by extending the openings OP. For example, one of the openings OP may extend between the first group of channel structures 220G1 and the second group of channel structures 220G2, and at least one of the third material layers 210C may be separated into source select lines. A source select line formed as one layer may be separated into a first source select line and a second source select line.

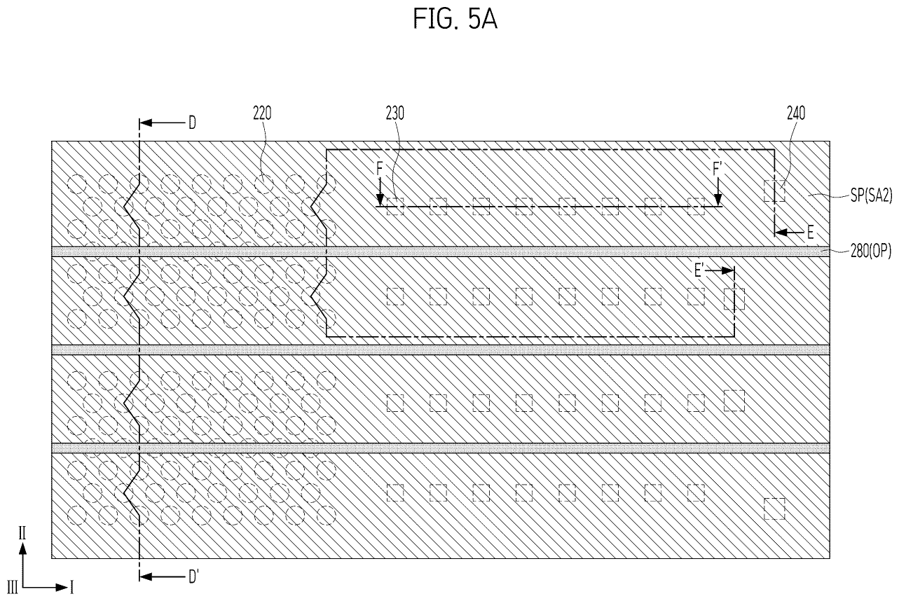

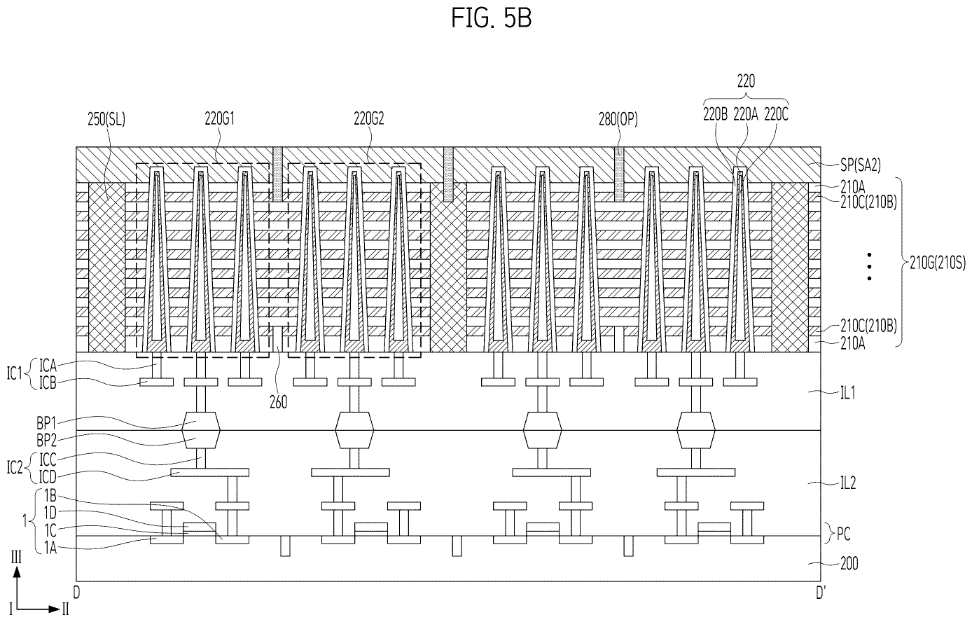

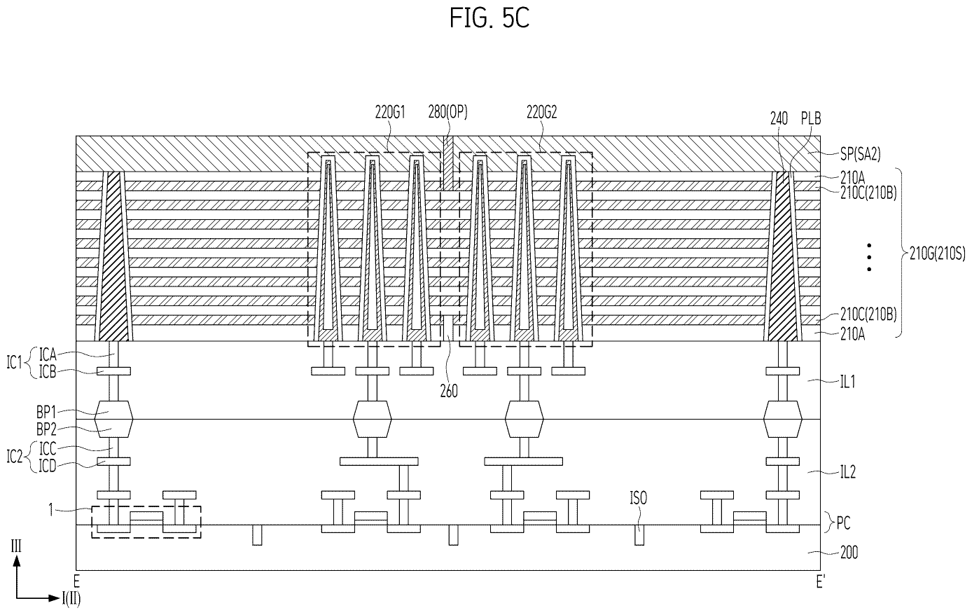

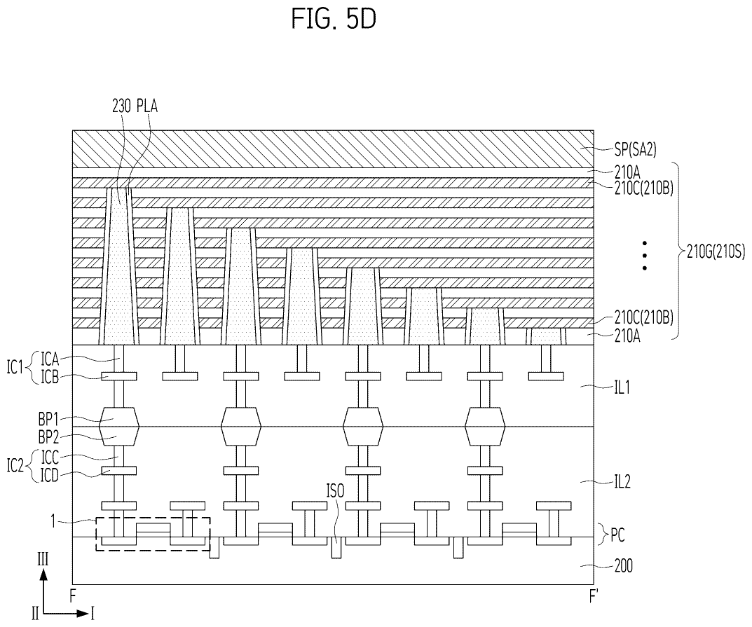

Referring to FIGS. 5A to 5D, source separation structures 280 may be formed in each of the openings OP, respectively. For example, the source separation structures 280 may each include an insulating material such as oxide or nitride. In an embodiment, the source separation structures 280 may be formed using a deposition process, such as chemical vapor deposition (CVD) or atomic layer deposition (ALD), followed by a planarization or etching step to define the structures within the openings.

Subsequently, the first sacrificial layer SA1 may be removed. For example, the first sacrificial layer SA1 and the source separation structures 280 may be planarized so that upper surfaces of the sacrificial patterns SP are exposed.

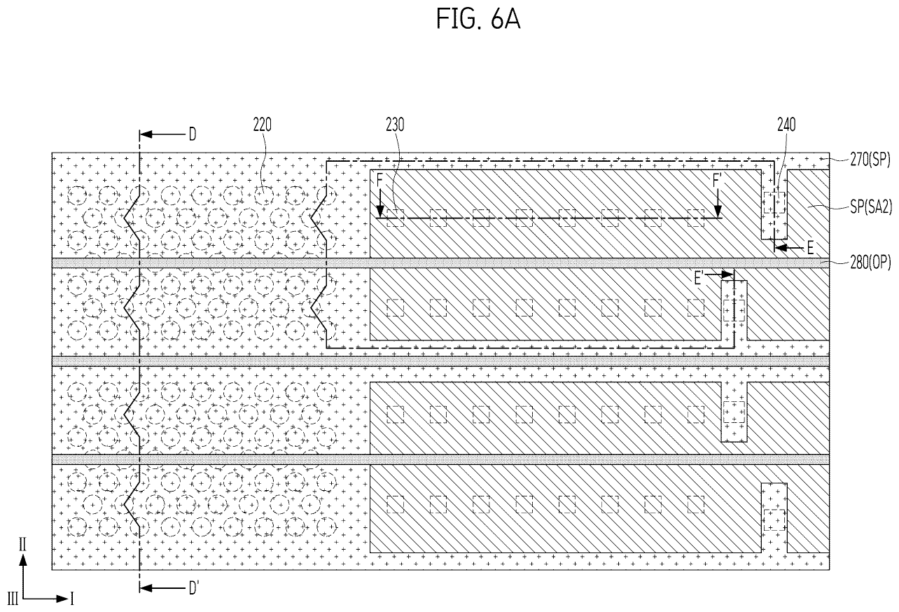

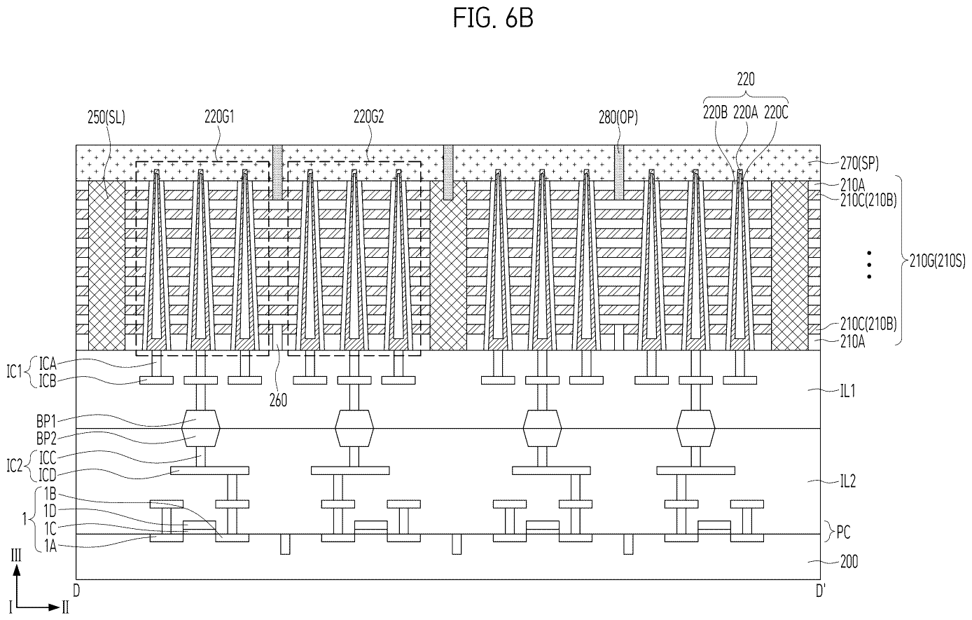

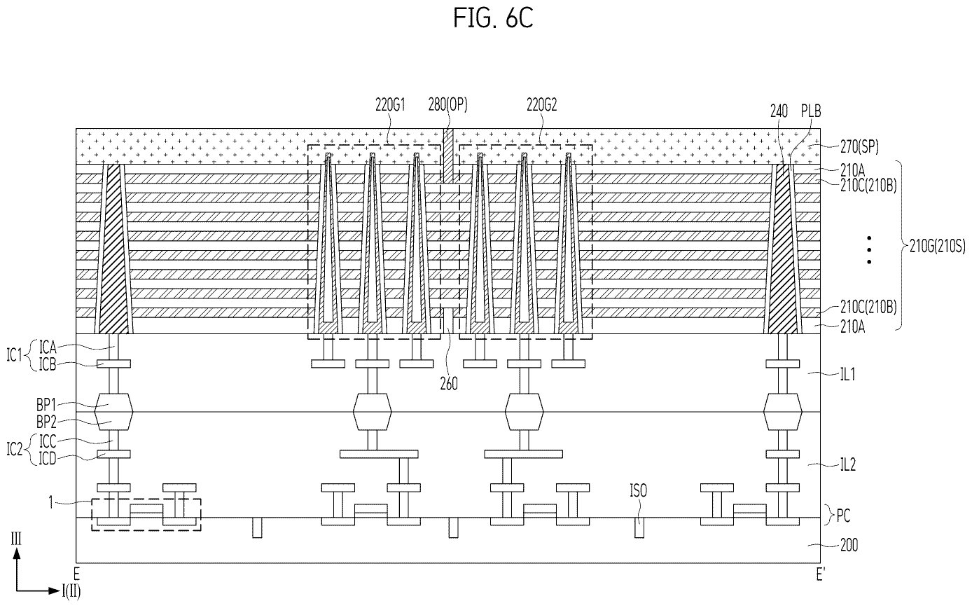

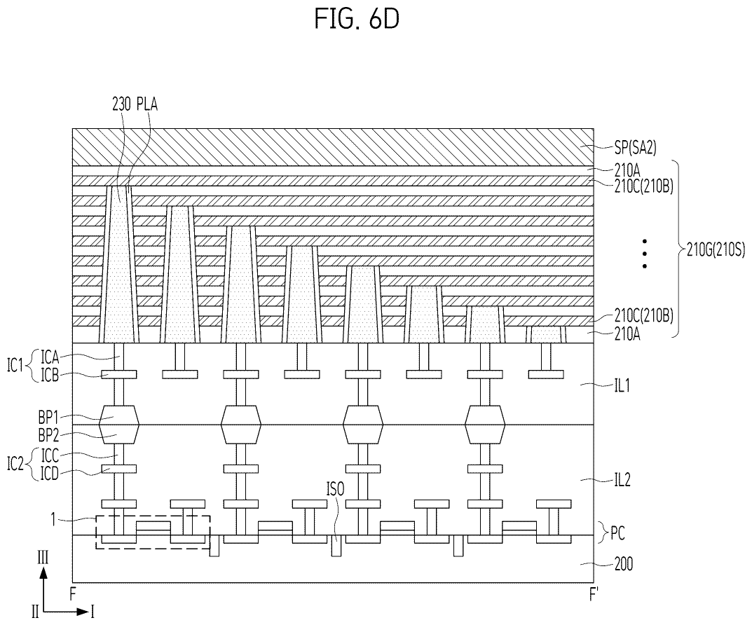

Referring to FIGS. 6A to 6D, the sacrificial patterns SP may be removed. For example, the sacrificial patterns SP may each include a different material from the source separation structures 280, and may thus be selectively etched and removed. In some embodiments, a selective isotropic etch may be employed to remove the sacrificial patterns SP without substantially affecting the surrounding insulating materials. In such a case, the channel structures 220 may be exposed. For example, the etching process may be followed by a cleaning process to remove any etch residues and to prepare the exposed surfaces for subsequent processing.

Some of the sacrificial patterns SP may remain. For example, the sacrificial patterns SP formed on the contact vias 230 may remain. A mask pattern may be formed so that the sacrificial patterns SP in regions corresponding to the channel structures 220 and the contact plugs 240 may be removed and the sacrificial patterns SP in regions corresponding to the contact vias 230 may remain. The sacrificial patterns SP corresponding to the channel structures 220 and the contact plugs 240 may be selectively removed using the mask pattern.

Subsequently, the channel layer 220A may be exposed by partially removing the memory layer 220B of the channel structures 220. For example, the channel layers 220A of the channel structures 220 may be exposed by removing portions of the memory layers 220B of the channel structures 220 protruding from the gate structure 210G.

Subsequently, source patterns 270 connected to the channel structures 220 may be formed. For example, a source layer may be formed to fill regions where the sacrificial patterns SP are removed. The source layer may be deposited using a conformal deposition technique such as chemical vapor deposition (CVD), ensuring that the recessed regions between the source separation structures 280 are adequately filled. For example, the source layer may cover the source separation structures 280. Subsequently, the source layer may be planarized, for instance by chemical mechanical polishing (CMP), so that upper surfaces of the source separation structures 280 are exposed. In such a case, the source layer may be separated into the source patterns 270. For example, the source patterns 270 may each include polysilicon, although other conductive materials such as doped silicon or metal silicide may also be used in some embodiments.

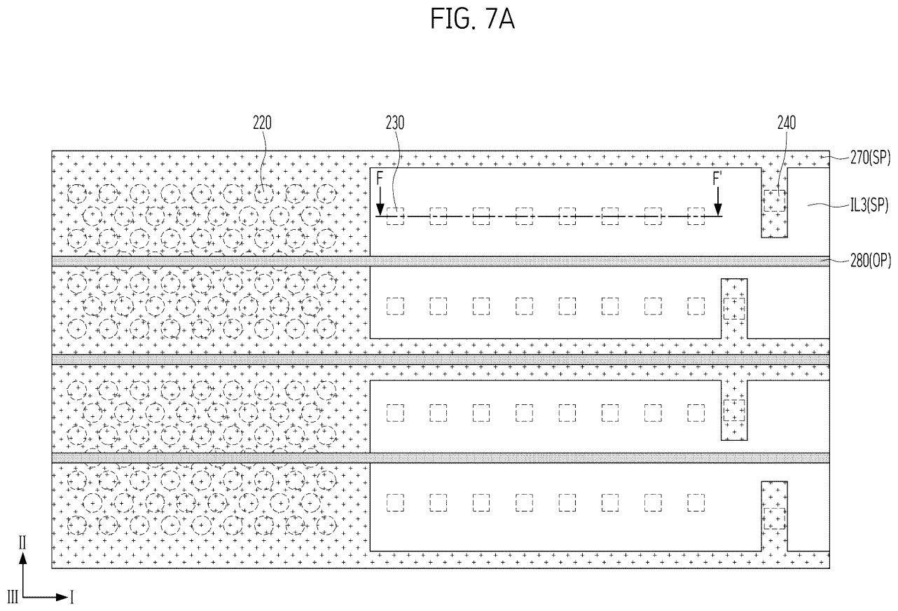

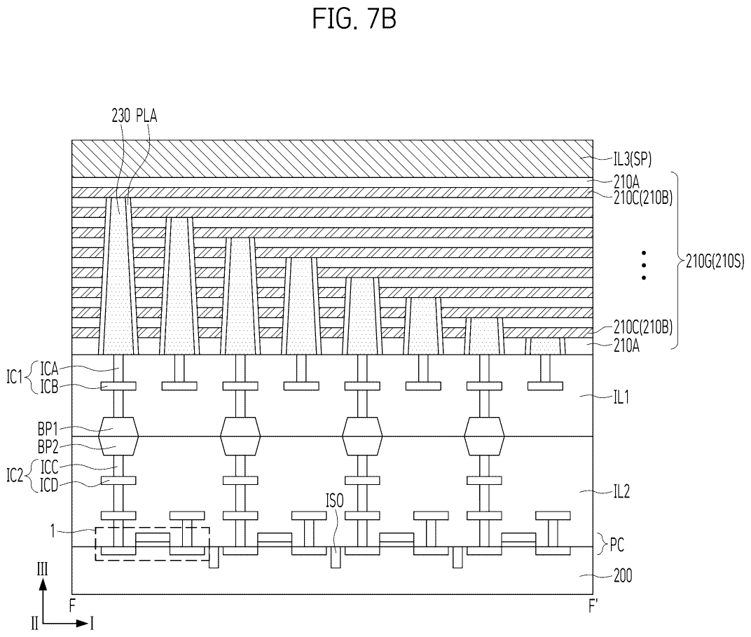

Referring to FIGS. 7A and 7B, the sacrificial patterns SP corresponding to the contact vias 230 may be removed. The removal may be performed using a selective etching process that targets the material of the sacrificial patterns without substantially affecting adjacent structures. Subsequently, a third interlayer insulating layer IL3 may be formed to fill regions where the sacrificial patterns SP are removed. The third interlayer insulating layer IL3 may be deposited using a technique such as plasma-enhanced chemical vapor deposition (PECVD) to ensure good step coverage and gap-fill characteristics. For example, the third interlayer insulating layer IL3 may include an insulating material such as oxide.

According to an embodiment of the present disclosure, some of the source patterns 270 may be separated into first and second source patterns by the source separation structure 280. The first group of channel structures 220G1 may be connected to the first source pattern, and the second group of channel structures 220G2 may be connected to the second source pattern. In addition, the first and second source patterns may be connected to first and second contact plugs, respectively. For example, the first and second contact plugs may be connected to first and second source select transistors, respectively.

In such a case, even though a voltage is applied to the first source pattern through the first source select transistor and the first contact plug, the second group of channel structures 220G2 might not be affected, and even though a voltage is applied to the second source pattern through the second source select transistor and the second contact plug, the first group of channel structures 220G1 might not be affected. This configuration enables electrical isolation between the first and second groups of channel structures, allowing independent control of each group without interference.

The source patterns connected to different groups of channel structures may be separated by the source separation structure, and the source patterns may be selectively controlled through the source select transistors electrically connected respectively to the source patterns. That is, it is possible to prevent or reduce the occurrence of electrical interference between the different groups of channel structures, and it is possible to selectively apply a voltage to a desired group of channel structures. Accordingly, it is possible to improve the reliability of the semiconductor device. This structural separation and selective control mechanism enhances operational precision and minimizes cross-talk between independently driven channel groups.

According to the method described above, the sacrificial separation structure SS may be formed in advance in consideration of a region where the source separation structure 280 is to be formed. For example, the sacrificial separation structure SS may be formed in advance to be located between the different groups of channel structures so that the source separation structure 280 may distinguish different groups of channel structures from each other. In such a case, the first and second groups of channel structures 220G1 and 220G2 may be distinguished from each other by removing the sacrificial separation structure SS in a subsequent process and then extending the opening OP.

In addition, the source patterns 270 may be formed spaced apart from each other. For example, the source patterns may be formed spaced apart from each other rather than being formed as one layer, by the source separation structure 280. That is, the first group of channel structures 220G1 may be connected to the first source pattern, and the second group of channel structures 220G2 may be connected to the second source pattern. In addition, source transistors for controlling the source patterns 270 may be formed. In such a case, by controlling the source patterns 270 through the respective source transistors, it is possible to reduce the electrical interference between the different groups of channel structures. Accordingly, it is possible to improve the reliability of the semiconductor device.

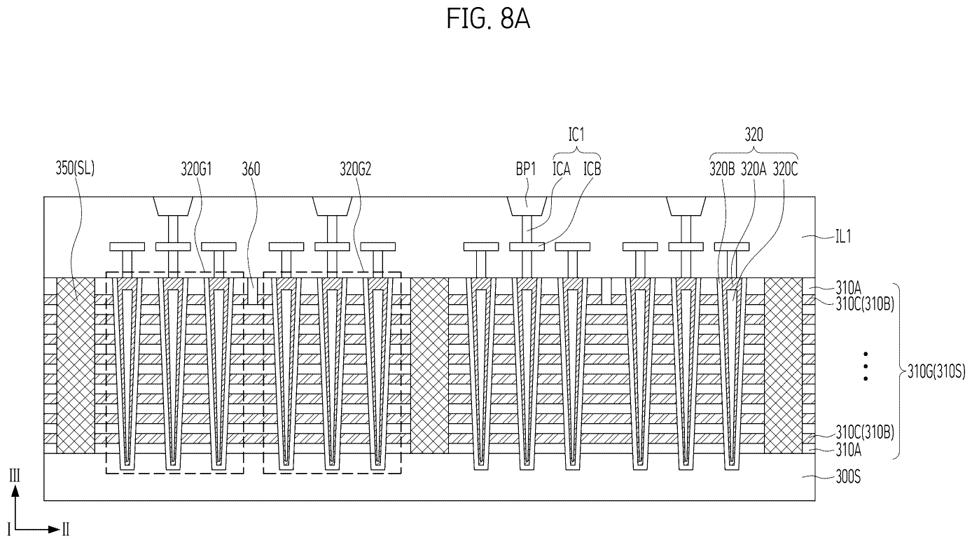

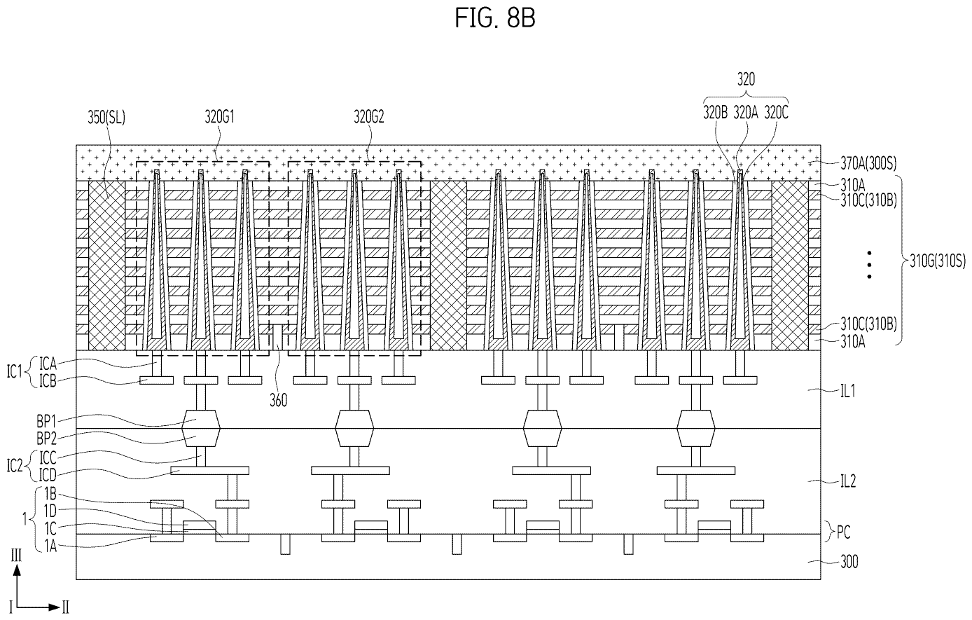

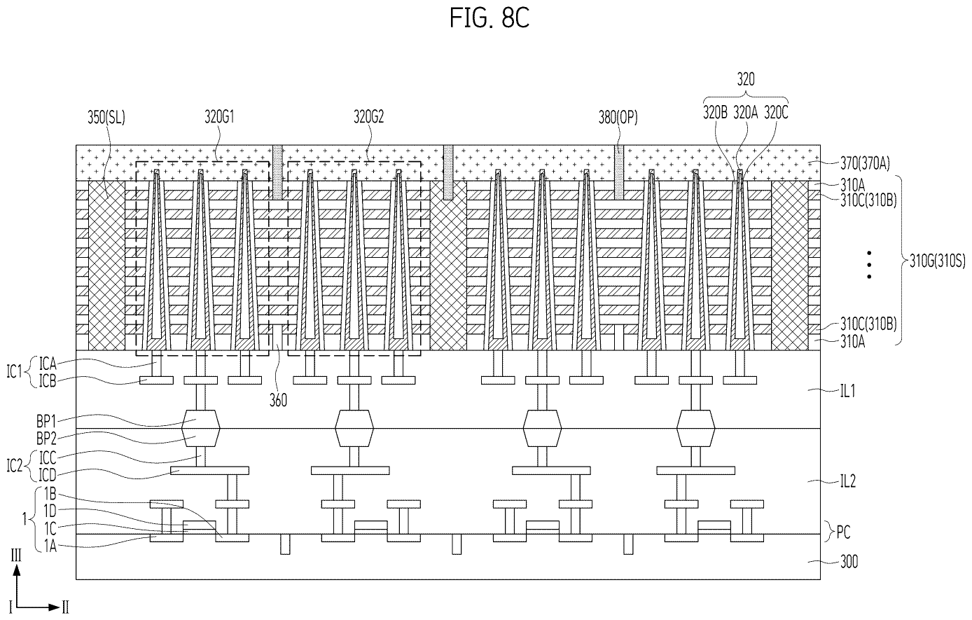

FIGS. 8A, 8B, and 8C are diagrams illustrating a method of manufacturing a semiconductor device in accordance with an embodiment of the present disclosure. Hereinafter, content overlapping with previously described content will be omitted.

Referring to FIG. 8A, a stack 310S may be formed by alternately stacking first material layers 310A and second material layers 310B on a cell substrate 300S.

Subsequently, multiple channel structures 320 extending through the stack 310S may be formed. Each of the channel structures 320 may include a channel layer 320A, a memory layer 320B surrounding the channel layer 320A, and an insulating core 320C located in the channel layer 320A.

Subsequently, a drain separation structure 360 extending through the stack 310S may be formed. However, in a variation of this embodiment, the drain separation structure 360 may be formed after a slit structure 350 is formed.

Subsequently, a slit SL extending through the stack 310S may be formed. Subsequently, a gate structure 310G may be formed by replacing the second material layers 310B with third material layers 310C through the slit SL.

Subsequently, a slit structure 350 may be formed in the slit SL. Subsequently, a first interlayer insulating layer IL1 may be formed on the gate structure 310G. Subsequently, a first interconnection structure IC1 and first bonding pads BP1 located on the first interconnection structure IC1 may be formed in the first interlayer insulating layer IL1. For example, the first interconnection structure IC1 may include first vias ICA and first wiring lines ICB.

Referring to FIG. 8B, a peripheral circuit wafer and a cell wafer may be bonded to each other. For example, second bonding pads BP2 of the peripheral circuit wafer and the first bonding pads BP1 of the cell wafer may be bonded to each other. For example, the peripheral circuit wafer may include a peripheral circuit board 300, a peripheral circuit PC, a second interlayer insulating layer IL2, a second interconnection structure IC2, and the second bonding pads BP2. The cell wafer may include the cell substrate 300S, the gate structure 310G, the channel structures 320, the slit structure 350, the drain separation structure 360, the first interlayer insulating layer IL1, the first interconnection structure IC1, and the first bonding pads BP1.

Subsequently, the channel structures 320 may be exposed by removing the cell substrate 300S.

Subsequently, the channel layer 320A may be exposed by partially removing the memory layer 320B of the channel structures 320. Subsequently, a source layer 370A connected to the channel layers 320A of the channel structures 320 may be formed. For example, the source layer 370A may include polysilicon.

Referring to FIG. 8C, openings OP extending through the source layer 370A may be formed. For example, the openings OP may extend between a first group of channel structures 320G1 and a second group of channel structures 320G2. In this case, the source layer 370A may be separated into source patterns 370 by the openings OP. For example, the source layer 370A may be separated into a first source pattern connected to the first group of channel structures 320G1 and a second source pattern connected to the second group of channel structures 320G2. For example, The openings OP may be formed using an anisotropic etching process to ensure vertical sidewalls and precise pattern definition. Subsequently, source separation structures 380 may be formed in the openings OP, respectively. The source separation structures 380 may include insulating materials, and may serve to electrically isolate the adjacent source patterns. This configuration may allow the first and second source patterns to be independently biased, thereby supporting selective operation of the corresponding channel structure groups.

According to the method described above, the openings OP for forming the source separation structures 380 may be formed after the peripheral circuit wafer and the cell wafer are bonded to each other. In such a case, the openings OP may be selectively formed at desired locations. In a process of forming the openings OP, the source layer 370A may be separated into the source patterns 370 respectively connected to different groups of channel structures.

Although embodiments according to the technical concepts of the present disclosure have been described above with reference to the accompanying drawings, this is only for describing the embodiments according to the concept of the present disclosure, and the embodiments are not limited to the above embodiments. Various substitutions, modifications, and changes for the embodiments may be made by those skilled in the art, to which the present disclosure pertains, without departing from the technical concepts and scope of the present disclosure as defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a substrate including a cell region and a peripheral circuit region spaced apart from the cell region in a first direction;
a first source select line located in the cell region and extending in the first direction;
a second source select line spaced apart from the first source select line in a second direction intersecting the first direction;
a first source pattern located on the first source select line;
a second source pattern located on the second source select line;
a first group of channel structures extending into the first source pattern through the first source select line; and
a second group of channel structures extending into the second source pattern through the second source select line.

2. The semiconductor device of claim 1, further comprising a source separation structure located between the first source pattern and the second source pattern and extending between the first source select line and the second source select line.

3. The semiconductor device of claim 1, wherein the first source pattern extends from the cell region to the peripheral circuit region, and
wherein the second source pattern extends from the cell region to the peripheral circuit region.

4. The semiconductor device of claim 3, further comprising:
a first source select transistor located in the peripheral circuit region;
a second source select transistor located in the peripheral circuit region;
a first contact plug located between the first source select transistor and the first source pattern and electrically connecting the first source select transistor and the first source pattern to each other; and
a second contact plug located between the second source select transistor and the second source pattern and electrically connecting the second source select transistor and the second source pattern to each other.

5. The semiconductor device of claim 1, comprising a gate structure including the first source select line, the second source select line, and word lines located below the first source select line and below the second source select line.

6. The semiconductor device of claim 5, wherein the substrate further includes a contact region located between the cell region and the peripheral circuit region.

7. The semiconductor device of claim 6, further comprising contact vias located in the contact region and respectively connected to the first source select line, the second source select line, and the word lines.

8. The semiconductor device of claim 5, wherein the gate structure further comprises:
a first drain select line located below the word lines and corresponding to the first source select line; and
a second drain select line spaced apart from the first drain select line in the second direction and corresponding to the second source select line.

9. The semiconductor device of claim 8, further comprising a drain separation structure located between the first drain select line and the second drain select line.

10. The semiconductor device of claim 1, further comprising:
a peripheral circuit located on the substrate;
a first interconnection structure located on the peripheral circuit;
a bonding structure located on the first interconnection structure; and
a second interconnection structure located on the bonding structure.

11. A method of manufacturing a semiconductor device, the method comprising:
forming a first sacrificial layer;
forming a sacrificial separation structure in the first sacrificial layer;
forming a second sacrificial layer on the first sacrificial layer;
forming a stack by alternately stacking first material layers and second material layers on the second sacrificial layer;
forming a first group of channel structures and a second group of channel structures that extend into the second sacrificial layer through the stack;
forming a slit extending through the stack;
forming a gate structure by replacing the second material layers with third material layers through the slit;
forming an opening by removing the sacrificial separation structure;
separating the second sacrificial layer into sacrificial patterns by extending the opening; and
forming a source separation structure in the opening.

12. The method of claim 11, wherein the opening extends between the first group of channel structures and the second group of channel structures.

13. The method of claim 11, wherein at least one of the third material layers is separated by extending the opening.

14. The method of claim 13, wherein at least one of the third material layers is separated into source select lines.

15. The method of claim 11, further comprising:
removing the sacrificial patterns; and
forming a first source pattern connected to the first group of channel structures and a second source pattern connected to the second group of channel structures.

16. The method of claim 15, wherein each of the first group of channel structures and the second group of channel structures includes a channel layer and a memory layer surrounding the channel layer, and
wherein after the sacrificial patterns are removed, the channel layers of the first group of channel structures and the channel layers of the second group of channel structures are exposed by partially removing the memory layers of the first group of channel structures and the memory layers of the second group of channel structures.

17. The method of claim 15, further comprising:
forming a first contact plug and a second contact plug that extend through the stack;
forming a first source select transistor and a second source select transistor.

18. The method of claim 17, wherein the first source select transistor and the first source pattern are electrically connected to each other through the first contact plug, and
wherein the second source select transistor and the second source pattern are electrically connected to each other through the second contact plug.

19. A method of manufacturing a semiconductor device, the method comprising:
forming a stack by alternately stacking first material layers and second material layers on a substrate;
forming a first group of channel structures and a second group of channel structures that extend into the substrate through the stack;
forming a slit extending through the stack;
forming a gate structure by replacing the second material layers with third material layers through the slit;
exposing the first group of channel structures and the second group of channel structures by removing the substrate;
forming a source layer connected to the first group of channel structures and the second group of channel structures;
forming an opening extending between the first group of channel structures and the second group of channel structures through the source layer; and
forming a source separation structure in the opening.

20. The method of claim 19, wherein the source layer is separated into a first source pattern and a second source pattern by the opening, the first source pattern being connected to the first group of channel structures, and the second source pattern being connected to the second group of channel structures.

21. The method of claim 20, wherein each of the first group of channel structures and the second group of channel structures includes a channel layer and a memory layer surrounding the channel layer, and
wherein after the substrate is removed, the channel layers of the first group of channel structures and the channel layers of the second group of channel structures are exposed by partially removing the memory layers of the first group of channel structures and the memory layers of the second group of channel structures.

22. The method of claim 20, further comprising:
forming a first contact plug and a second contact plug that extend through the stack; and
forming a first source select transistor and a second source select transistor.

23. The method of claim 22, wherein the first source select transistor and the first source pattern are electrically connected to each other through the first contact plug, and
wherein the second source select transistor and the second source pattern are electrically connected to each other through the second contact plug.

24. The method of claim 19, wherein at least one of the third material layers is separated by extending the opening.

25. The method of claim 24, wherein at least one of the third material layers is separated into source select lines.

26. A semiconductor device comprising:
a substrate including a cell region;
a first source select line located in the cell region and extending in a first direction;
a second source select line located in the cell region and extending in the first direction;
a first source pattern located on the first source select line;
a second source pattern located on the second source select line;
channel structures extending into the first and second source patterns through the first and second source select lines respectively,
wherein the first source select line and the first source pattern are separated from the second select line and the second source pattern by a source separation structure.

27. The semiconductor device of claim 26,
wherein the substrate further includes a peripheral circuit region spaced apart from the cell region in the first direction,
wherein the first source pattern extends from the cell region to the peripheral circuit region, and
wherein the second source pattern extends from the cell region to the peripheral circuit region.

28. The semiconductor device of claim 27, further comprising:
a first source select transistor located in the peripheral circuit region;
a second source select transistor located in the peripheral circuit region;
a first contact plug located between the first source select transistor and the first source pattern and electrically connecting the first source select transistor and the first source pattern to each other; and
a second contact plug located between the second source select transistor and the second source pattern and electrically connecting the second source select transistor and the second source pattern to each other.

29. The semiconductor device of claim 27, a gate structure comprises:
the first source select line;
the second source select line, and
word lines located below the first source select line and below the second source select line.

30. The semiconductor device of claim 29, wherein the substrate further includes a contact region located between the cell region and the peripheral circuit region.

31. The semiconductor device of claim 30, further comprising contact vias located in the contact region and respectively connected to the first source select line, the second source select line, and the word lines.

32. The semiconductor device of claim 29, wherein the gate structure further comprises:
a first drain select line located below the word lines and corresponding to the first source select line; and
a second drain select line spaced apart from the first drain select line in the second direction and corresponding to the second source select line.

33. The semiconductor device of claim 32, further comprising a drain separation structure located between the first drain select line and the second drain select line.

34. The semiconductor device of claim 26, further comprising:
a peripheral circuit located on the substrate;
a first interconnection structure located on the peripheral circuit;
a bonding structure located on the first interconnection structure; and
a second interconnection structure located on the bonding structure.
